(19) United States
(12) Patent Application Publication
(10) Pub. No.: US 2026/0105236 A1
(43) Pub. Date: Apr. 16, 2026

(54) METHOD AND SYSTEM FOR OBSTACLE AVOIDANCE USING RECTILINEAR STEINER MINIMAL TREE LENGTH ESTIMATION

(71) Applicant: KING FAHD UNIVERSITY OF PETROLEUM AND MINERALS, Dhahran (SA)

(72) Inventors: Umair Farooq SIDDIQI, Dhahran (SA); Sadiq Mohammed Sait, Dhahran (SA)

(73) Assignee: KING FAHD UNIVERSITY OF PETROLEUM AND MINERALS, Dhahran (SA)

(21) Appl. No.: 18/912,865

(22) Filed: Oct. 11, 2024

(51) Int. Cl. G06F 30/3947; G06F 30/3953

(52) U.S. Cl. CPC G06F 30/3947; G06F 30/3953

(57) ABSTRACT

A wired circuit and a method for wiring a circuit with a minimum length of wire utilizing obstacle avoidance rectilinear Steiner minimal tree (OARSMT) routing. A circuit diagram is obtained which contains components and nets of pins, with obstacles represented by the components. The pin and obstacle data are encoded into m×m images, which are resized to m′×m′ images using Gaussian filtering and average pooling. The resized images are processed through three convolutional neural network layers to generate feature maps. An output layer predicts the OARSMT length of wire, providing an estimation of the minimal wire length without running through obstacles needed during wire routing of the circuit. ReLU activation layers are applied to isolate pin and obstacle features and predicting the OARSMT length of wire within a mean runtime of 15 ms, providing efficient wire routing for circuits without running wires through obstacles.

### STATEMENT REGARDING PRIOR DISCLOSURE BY THE INVENTORS

Aspects of this technology are described in an article “Obstacle Avoidance Rectilinear Steiner Minimal Tree Length Estimation Using Deep Learning” presented at the 2023 22nd International Symposium on Communications and Information Technologies, Sydney, Australia, on Oct. 16, 2023, which is incorporated herein by reference in its entirety.

### BACKGROUND

### Technical Field

The present disclosure is directed to electronic design automation (EDA), particularly to methods and systems for estimating the length of obstacle-avoiding rectilinear Steiner minimal trees (OARSMTs) in very-large-scale integration (VLSI) physical design using deep learning techniques.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

The physical design phase of electronic design automation (EDA) involves transforming a logic design, expressed as a gate-level netlist, into a physical layout suitable for the fabrication of integrated circuits (ICs). The physical design includes a process encompassing a series of hierarchical, top-down procedures, including logic partitioning, floorplanning, cell placement, and both global and detailed routing. Each of these steps tackles (nondeterministic polynomial) NP-hard problems, leading to substantial computational complexity and time-consuming design cycles.

A key objective during a placement phase is minimizing a total length of wire of all nets, as the length of the wire directly affects a performance, power consumption, and manufacturing costs of the design. Accurate length of wire estimation enables better placement decisions, leading to optimized layouts. Traditional methods, such as half-perimeter wire length (HPWL), are computationally efficient but often lack precision, for example, in presence of obstacles within a routing grid. These obstacles may include pre-routed nets, antenna jumpers for reliability enhancement, and other components common in modern very-large-scale integration (VLSI) designs.

The rectilinear Steiner minimal tree (RSMT) problem involves finding a shortest tree connecting all terminals of a net using only horizontal and vertical segments. Solving the exact RSMT is NP-complete and is approached using heuristics. When obstacles are introduced, the problem becomes the obstacle-avoiding rectilinear Steiner minimal tree (OARSMT), which is also NP-complete. Heuristic methods for generating OARSMTs are often computationally expensive, making them impractical for rapid wire length estimation during the placement phase.

In recent years, machine learning (ML) and deep learning (DL) techniques have been incorporated into the physical design process to improve both speed and quality. DL models have been applied to tasks such as predicting design rule checking (DRC) violations without performing routing, forecasting outcomes of legalization algorithms, predicting post-routing metal layer congestion from technology-specific gate-level netlists, and generating congestion heatmaps based on placement data. These models aim to reduce design iterations by providing accurate predictions based on preliminary information.

However, despite these advances, existing technologies still fall short when it comes to rapidly predicting length of wire in the presence of obstacles. For instance, statistical methods have been employed to estimate length of wires based on post-floorplanning data, and graphics processing units (GPUs) have been used to accelerate HPWL calculations. Other approaches, such as bundling techniques, offer fast predictions but are limited to nets with a small number of pins.

US20230186058A1 describes a multiterminal obstacle-avoiding pathfinding system that utilizes deep image learning. In this method, the routing problem is reduced to an image-to-image manipulation problem by exploiting the two-dimensional grid structure inherent in wire routing. The multiterminal net inputs and outputs are mapped onto two-dimensional bitmaps, and a multistage neural network processes these inputs. All tiles with individual obstacle and terminal indicators are fed as machine learning features into the input channels of the generator, resulting in an input dimension determined by the total number of features of the nxn tile bitmap.

US20230274068A discloses wire routing on a multi-layer substrate where preferred and non-preferred directions are separately analyzed, with non-preferred directions potentially having curved paths. A Steiner tree is utilized for routing optimization. However, the method is a complex and time-consuming.

Each of the aforementioned disclosures suffers from one or more drawbacks hindering their adoption. The drawbacks include, but are not limited to, the lack of methods for rapid and accurate prediction of OARSMT length of wires that efficiently handle any configuration of pin locations and obstacle distributions. Specifically, existing techniques do not involve the separate processing of terminal and obstacle maps through Gaussian filters to reduce image dimensions, followed by applying a streamlined convolutional neural network architecture to extract high-level features, and then using fully connected layers to predict the length of wire.

Accordingly, there exists a need for an efficient and accurate method for predicting the length of wire between pins on a circuit board by using obstacle-avoiding rectilinear Steiner minimal trees in VLSI physical design. There is a need for a method that is capable of estimating any set of pin configurations and obstacle distributions, providing rapid predictions suitable for use during the placement phase.

### SUMMARY

In an exemplary embodiment, a method for wiring a circuit with a minimum length of wire is described. The method includes obtaining a circuit diagram of the circuit, wherein the circuit diagram includes a plurality of components and a plurality of nets of pins, wherein each net of pins comprises a source pin and one or more sink pins, and wherein each of the plurality of components are obstacles to placing wiring. The method further includes encoding, based on the circuit diagram, an m×m pin image by placing a one at each pin location on a first routing grid and a zero at each location on the first routing grid which does not include a pin. Additionally, the method includes encoding, based on the circuit diagram, an m×m obstacle image by placing ones at locations on a second routing grid which represent an obstacle and a zero at each location on the second routing grid which does not include the obstacle. The method proceeds by resizing the m×m pin image to form an m′×m′ pin image, where m′<<m, and resizing the m×m obstacle image to form an m′×m′ obstacle image, where m′<<m. The resized pin and obstacle images are then applied to a series of three convolutional neural network layers, generating an output series of feature maps. The method includes applying the output series of feature maps to an output layer and predicting, by the output layer, an obstacle-avoiding rectilinear Steiner minimal tree (OARSMT) length of wire needed to connect each net of pins. The method includes estimating the minimum length of wire needed to connect all of the nets of pins; and generating, with a placer, a wiring layout using the minimum length of wire; and connecting, with a wiring router, each of the nets of pins with the minimum length of wire to form the wired circuit based on the wiring layout.

In another exemplary embodiment, a wired circuit is described. The wired circuit includes a circuit diagram comprising a plurality of components and a plurality of nets of pins, wherein each net of pins comprises a source pin and one or more sink pins, and wherein each of the plurality of components are obstacles to placing wiring. The wired circuit further includes a first data encoder configured to encode, based on the circuit diagram, an m×m pin image by placing a one at each pin location on a first routing grid and a zero at each location on the first routing grid which does not include a pin. Additionally, the wired circuit includes a second data encoder configured to encode, based on the circuit diagram, an m×m obstacle image by placing ones at locations on a second routing grid which represent an obstacle and a zero at each location on the second routing grid which does not include the obstacle. The wired circuit includes a first Gaussian filter and a first average pooling layer configured to resize the m×m pin image to form an m′×m′ pin image, where m′<<m, a second Gaussian filter and a second average pooling layer configured to resize the m×m obstacle image to form an m′×m′ obstacle image, where m′ <<m. The wired circuit further includes a series of three convolutional neural network layers configured to receive the m′×m′ pin image and the m′×m′ obstacle image and generate an output series of feature maps. An output layer is configured to receive the output series of feature maps and predict an obstacle-avoiding rectilinear Steiner minimal tree (OARSMT) length of wire needed to connect each net of pins. A computing device is configured to estimate the minimum length of wire needed to connect all of the nets of pins, a placer is configured to generate a wiring layout using the minimum length of wire; and a wiring router is configured to connect each of the nets of pins with the minimum length of wire to form the wired circuit based on the wiring layout.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A illustrates a routing grid system utilized during a physical design phase of very-large-scale integration (VLSI) circuits.

FIG. 1B illustrates an exemplary routing solution within a routing grid system.

FIG. 1C illustrates an alternative routing solution that further improves a length of wire by adjusting path between the pins.

FIG. 1D illustrates a process of obstacle-avoiding rectilinear Steiner minimal tree (OARSMT) computation and associated wire-length estimation within a routing grid.

FIG. 2 illustrates a system for determining a length of the OARSMT using an encoding and deep learning model, according to certain embodiments.

FIG. 3 illustrates a wired circuit with convolutional neural networks (CNNs) to predict the length of an OARSMT required to connect multiple pins, according to certain embodiments.

FIG. 4A illustrates a system for processing circuit data using a deep learning model, according to certain embodiments.

FIG. 4B illustrates an abstract structure of a system for processing circuit data, according to certain embodiments.

FIG. 4C illustrates a process having steps performed by each of CNN layers during processing of the input data, according to certain embodiments.

FIG. 4D illustrates a flattening layer implemented within the deep learning model, according to certain embodiments.

FIG. 5A is an exemplary illustration of a process of reducing the size of an input image using Gaussian filtering and average pooling for OARSMT computation, according to certain embodiments.

FIG. 5B shows the reduced images of FIG. 5A, according to certain embodiments.

FIG. 6 is an illustration of a non-limiting example of details of computing hardware used in the computing system, according to certain embodiments.

FIG. 7 is an exemplary schematic diagram of a data processing system used within the computing system, according to certain embodiments.

FIG. 8 is an exemplary schematic diagram of a processor used with the computing system, according to certain embodiments.

FIG. 9 is an illustration of a non-limiting example of distributed components which may share processing with the controller, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspects of this disclosure are directed to a system and method for determining a length of wire for obstacle-avoiding rectilinear Steiner minimal trees (OARSMTs) in integrated circuit design using deep learning techniques, during the placement phase of very-large-scale integration (VLSI) physical design. Conventional techniques for estimating length of wires, such as the half-perimeter wire length (HPWL), are computationally efficient but lack accuracy in the presence of obstacles on the routing grid. Existing heuristics for generating OARSMTs are computationally intensive and unsuitable for quick estimation, hindering the optimization of component placement and leading to increased design iterations.

The present disclosure relates to a system and a method that comprises a data encoding technique and a deep learning (DL) model to predict the OARSMT length for any configuration of pins and obstacles on a routing grid. The data encoding technique transforms grid information, including the locations of pins and the dimensions and obstacles of the routing grid, into two small images. Specifically, a first data encoder is configured to encode, based on the circuit diagram, an m×m pin image by placing a one at each pin location on a first routing grid and zeros elsewhere. A second data encoder similarly encodes an m×m obstacle image by placing ones at obstacle locations on a second routing grid and zeros elsewhere.

To reduce computational complexity and facilitate efficient processing, the method applies Gaussian filters and average pooling layers to resize the m×m pin and obstacle images into smaller m′×m′ images, where m′<<m. These resized images are input into a deep learning model comprising a series of three convolutional neural network (CNN) layers, which extract high-level feature maps. An output layer receives these feature maps and predicts the OARSMT length of wire needed to connect each net of pins.

By efficiently encoding problem information and utilizing a streamlined CNN architecture with fewer layers and smaller kernel sizes than conventional networks, the system provides high-quality and fast predictions of the OARSMT length. This enables quick estimation of the length of wires necessary during the placement phase, accounting for obstacles without the computational overhead of traditional heuristic methods. As a result, the system enhances the placement process by facilitating better component placement decisions, reducing design iterations, and improving the overall efficiency of the VLSI physical design process.

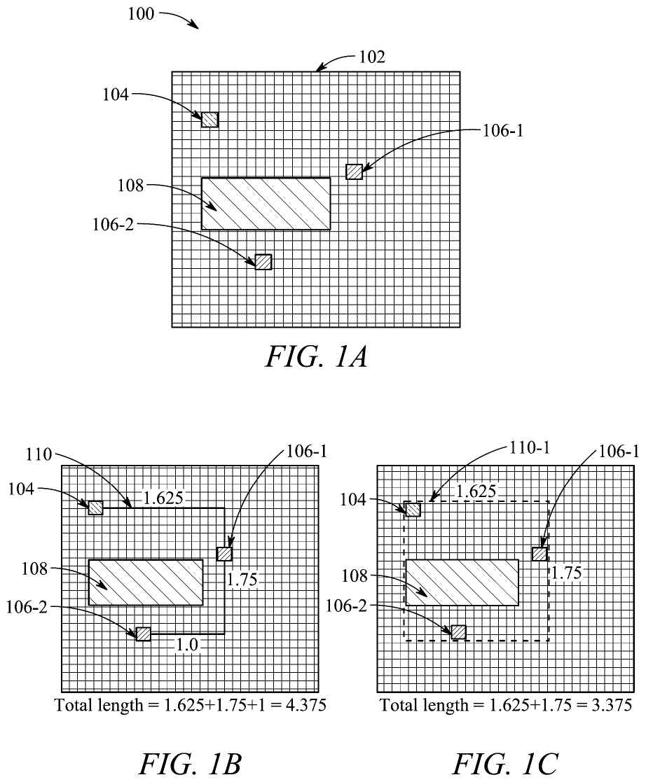

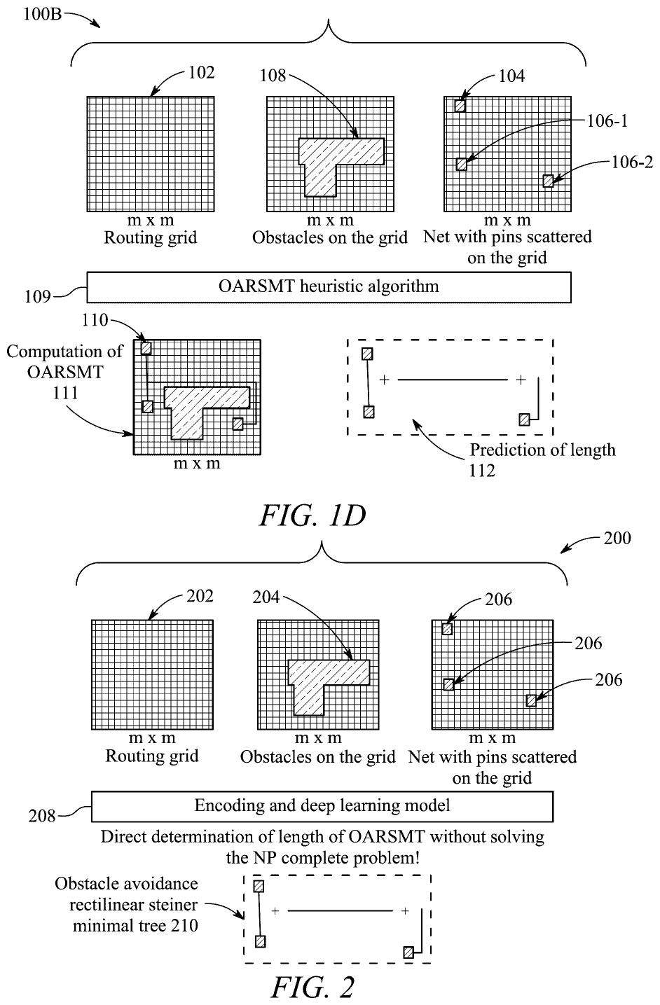

FIGS. 1A-1D illustrate a routing grid system 100 utilized during the physical design phase of very-large-scale integration (VLSI) circuits. The routing grid system 100 includes a routing grid 102 which is a two-dimensional matrix composed of intersecting horizontal and vertical lines, forming a network of potential routing paths. Each intersection point on the routing grid 102 represents a possible location for electrical connections or “routes” between different components of the circuit. The routing grid 02 is a precise layout of wires connecting various circuit elements while adhering to design constraints, such as minimal length of wire and obstacle avoidance.

Within the routing grid 102, there exists a plurality of pins, including a source pin 104 and one or more sink pins 106-1 and 106-2. A pin refers to a specific location on the grid where an electrical connection is made. A net is defined as a set of electrical connections that electrically connect multiple pins together, such that all connected pins are at the same electric potential at all times. The source pin 104 is the originating point of a net, representing the output of a driving component or signal source. Sink pins 106-1, 106-2 are the terminating points of the net, representing the inputs to one or more receiving components or devices. The source pin 104 and the sink pins 106-1, 106-2 are located anywhere on the grid, except for areas where obstacles 108 are located, and the respective interconnection is essential for signal propagation or power distribution within the integrated circuit (IC). The pins 104, 106-1, and 106-2 serve as the starting and ending points for wire routing across the routing grid 102.

Obstacles, such as obstacle 108, are physical structures present within the routing grid 102 that must be avoided during wire routing. Obstacle 108 represents pre-existing components or features, including pre-routed nets, power networks, antenna jumpers for reliability enhancement, or other circuit elements that occupy physical space on the routing grid 102. The obstacles 108 act as blockages, limiting the available routing paths and introducing complexity into the routing process. The presence of obstacle 108 necessitates the use of obstacle-avoidance strategies to ensure that the routing paths do not intersect with these areas, thereby adhering to design rules and preventing potential electrical conflicts or short circuits.

In one example, the obstacle 108 is depicted as a rectangular block with fixed position and dimensions on the routing grid 102. Its presence alters the available routing paths between the source pin 104 and sink pins 106-1 and 106-2. The routing algorithm must determine a path that connects all pins of the net while circumventing the obstacle, which can significantly impact the minimal achievable length of wire.

The process of finding the shortest possible path that connects the source pin 104 and sink pins 106-1 and 106-2 without intersecting any obstacles is known as the OARSMT problem. The OARSMT problem includes constructing a tree that connects all the pins using only horizontal and vertical wire segments (i.e., rectilinear paths 110) and further includes additional points called Steiner points to minimize the total length of wire. The OARSMT problem is proven to be NP-complete, meaning that it is computationally intensive to solve optimally, especially for large grids with many pins and obstacles.

Due to the computational complexity of the OARSMT problem, efficient estimation methods are essential for practical VLSI design. Rapid and accurate length of wire estimation methods are required to provide accurate predictions of the routing length of wire during the placement phase. Conventional estimation methods may ignore obstacles, leading to inaccuracies in the presence of real-world design complexities. Accurate length of wire estimation is crucial for optimizing component placement, minimizing delays, reducing power consumption, and ensuring the manufacturability of the integrated circuit.

FIG. 1B illustrates an exemplary routing solution within the routing grid system 100. The routing between pins 104, 106-1, and 106-2 is depicted by a line that follows a rectilinear path 110. The rectilinear path 110, as utilized in this context, consists of horizontal and vertical line segments that connect the pins while avoiding obstacles. The rectilinear path 110 is utilized in VLSI design due to its simplicity and efficiency. The rectilinear path 110 minimizes the complexity of wire routing by avoiding unnecessary bends or curves that could degrade signal integrity and increase design complexity. The total length of wire for the path depicted in FIG. 1B is determined by summing the horizontal and vertical segments that form the rectilinear path 110 between the pins. In this example, the total length of wire is calculated to be 4.375 units. A horizontal segment of length 1.625 units extends from pin 104 to the point where the path shifts vertically to avoid obstacle 108. A vertical segment of length 1.75 units connects this horizontal point to pin 106-1, manoeuvring around the obstacle 108. A vertical segment of length 1 unit continues from pin 106-1 to pin 106-2, completing the connection between the pins.

Thus, the total length of wire for this specific path is calculated by adding the horizontal and vertical segments:

$$Total length = 1.625 + 1.75 + 1 = 4.375$$

FIG. 1C presents a conventional alternative routing technique that further refines the length of wire by adjusting the path between the pins 104, 106-1, and 106-2. In an example, a half-perimeter wire-length (HPWL) routing technique is used. Using the technique, the length of the total wire is reduced to 3.375 units by adopting a bounding box that connects all the pins 104, 106-1, and 106-2. In an example, the bounding box is a smallest rectangle that can enclose all the points. A half-perimeter of this bounding box is taken as an estimate of the length of wire. Considering the bounding box, the length of the wire is calculated while still ensuring that the obstacle 108 is avoided. The refining allows for a more efficient use of available routing space. and reduces the total length of the wire required to connect the pins. In the given example, the bounding box 110-1 covers the all the pins 104, 106-1, and 106-2, and the half-perimeter is determined by horizontal segment of length 1.625 units that starts from the pin 104 reaching a column in the grid where pin 106-1 is located and the vertical segment of length 1.75 units that spans the row of the pin 104 to the pin 106-2. Thus, the total length of the total wire for the refined path is calculated by summing the horizontal and vertical distances:

$$Total length = 1.625 + 1.75 = 3.375 units$$

By calculating using the HPWL routing technique, the total length of the wire is shortened without compromising the need to avoid obstacles 108. The reduced length of the wire in this example demonstrates the value of determining the most efficient route, which can result in significant savings in terms of space, time, and resources during the design phase.

The OARSMT, as demonstrated by the solutions in FIG. 1B and FIG. 1C, are conventional techniques employed to minimize the total length of wire in the presence of obstacles. The OARSMT ensures that electrical connections between pins are made using the shortest possible rectilinear path 110 while successfully circumventing any obstructions that may be present, such as the obstacle 108.

Each pin, including pins 104, 106-1, and 106-2, occupies a specific location on the routing grid, and the challenge posed by the OARSMT problem lies in determining the shortest route between these pins while accounting for the limitations introduced by obstacles. The length of wire estimation methods depicted in these figures provide a fast and accurate way to predict the total length of wire, which can then be utilized to inform the placement and routing phases of VLSI design.

FIG. 1D illustrates a process 100B of OARSMT computation and the associated wire-length estimation within a routing grid 102 used in a VLSI physical design. The process is implemented in two steps using the OARSMT heuristic algorithm 109, which is employed to compute the shortest obstacle-avoiding rectilinear paths 110 between multiple pins on the routing grid 102.

Step 1 depicts a computation of the OARSMT 111. A set of pins 104 is scattered across the routing grid 102, representing the terminals of the net. These terminals must be connected using the shortest path that avoids the obstacles 108 present on the routing grid 102. The obstacle 108 is shown as a physical block that restricts available routing paths. The OARSMT computation involves determining the minimal rectilinear Steiner tree that connects the pins without passing through the obstacle 108. The computation is classified as NP-complete, meaning it is computationally intensive and challenging to solve optimally within practical time limits. Heuristic algorithms 109 are therefore used to approximate the solution. The resulting tree is represented by the dashed line, which indicates the rectilinear paths 110 connecting the pins while avoiding the obstacle.

Step 2 illustrates the process of calculating the total length of the OARSMT 112. The length of the wire is determined by summing the horizontal and vertical segments of the rectilinear paths 110. In one example, the length of wire is computed based on the total distance required to connect the pins 104 while avoiding the obstacle 108. Length of wire estimation directly impacts the overall performance of the integrated circuit, affecting signal delays and power consumption.

The routing grid 102 is divided into a fine grid structure to show the positioning of the pins (104, 106-2, and 106-2) and the obstacles 108, and the heuristic algorithm 109 computes a path that avoids obstacles while minimizing length of wire. These steps of the OARSMT computation promote the efficiency of the heuristic algorithm 109 in providing a near-optimal solution to the NP-complete problem, making it suitable for real-time applications in VLSI physical design. However, the calculation of the OARSMIT is computationally intensive using the conventional methods.

FIG. 2 illustrates a system 200 for determining the length of the OARSMT using an encoding and deep learning model 208 which avoids the computational complexity and inefficiency of solving the NP complete problem. The system 200 operates within a routing grid 202, which is a two-dimensional grid of dimensions m×m. The routing grid 202 serves as a structured network where electrical connections between a plurality of pins, as shown by 104, 106-1, and 106-2 in FIG. 1A, are made using rectilinear paths, as shown by 110 in FIG. 1A, composed exclusively of horizontal and vertical segments, adhering to the grid structure.

The routing grid 202 includes a plurality of obstacles 204 located within the grid. The obstacles 204 represent physical constraints, such as pre-routed nets, power networks, or other elements that must be avoided during the routing process. The presence of the obstacles 204 restricts the feasible routing paths between the pins and significantly increases the complexity of determining the shortest possible connections.

A set of pins 206 is distributed across the routing grid 202. Each pin 206 represents a terminal point or node that is part of a net requiring interconnection. In the context of physical design, the pins 206 are locations where electrical connections terminate or originate, and the objective is to connect them in a manner that minimizes the total length of wire while avoiding any obstacles 204.

The system 200 incorporates an encoding and deep learning model 208 designed to predict the length of the OARSMT without explicitly solving the NP-complete problem traditionally associated with such computations. The encoding process involves transforming the spatial information of the routing grid 202, including the locations of the obstacles 204 and the pins 206, into two distinct m×m images, a pin image and an obstacle image.

The pin image is generated by encoding the positions of the pins 206 on the routing grid 202. Each cell corresponding to a pin location is assigned a value of one, while all other cells are assigned a value of zero. Similarly, the obstacle image is created by encoding the positions of the obstacles 204. Cells representing obstacle locations are assigned a value of one, and all other cells are assigned a value of zero. The encoding effectively converts the spatial layout of the routing grid 202 into a numerical format suitable for processing by the deep learning model 208.

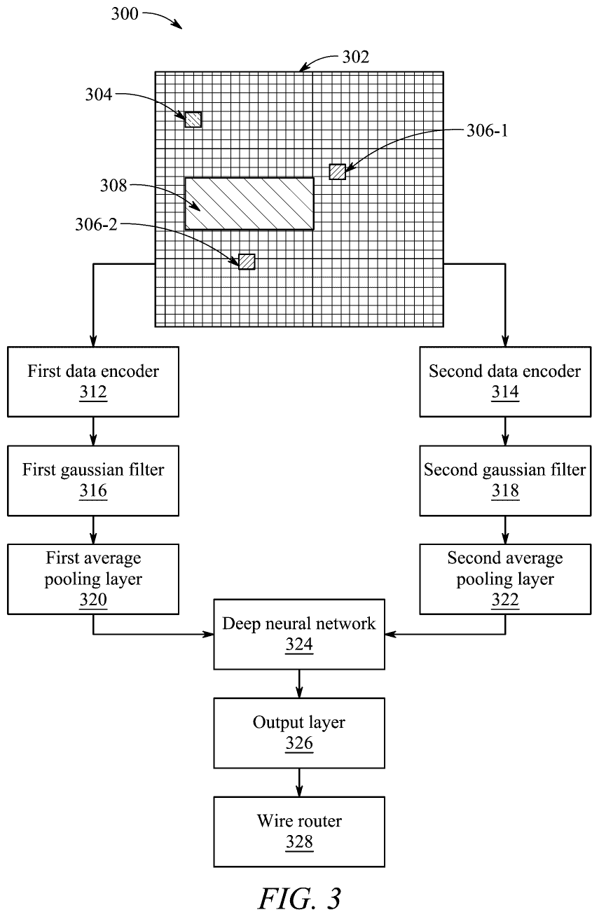

To enhance computational efficiency and reduce the dimensionality of the input data, the encoded pin and obstacle images are subjected to Gaussian filtering and average pooling operations. Such operations resize the original m×m images into smaller m′×m′ images, where m′<<m. The Gaussian filter, as described further with reference to FIG. 3, smoothens the images by reducing high-frequency components, while the average pooling layer down samples the images by summarizing local regions, thereby preserving essential spatial information in a more compact form.

The resized m′×m′ pin and obstacle images are then input to the deep learning model 208, which comprises a series of three convolutional neural network (CNN) layers followed by fully connected (FC) layers. The CNN layers are responsible for extracting high-level feature maps from the input images by applying convolutional operations with learnable kernels. These feature maps capture essential patterns and relationships between the pins and obstacles on the routing grid 202.

The output feature maps from the CNN layers are flattened and passed through the fully connected layers, which perform the final regression task of predicting the length of the OARSMT. The deep learning model outputs a scalar value representing the estimated length of wire required to connect all pins 206 while avoiding obstacles 204 on the routing grid 202.

The lower section of FIG. 2 depicts the OARSMT 210, illustrating the minimal rectilinear path that connects the pins 206 while circumventing the obstacles 204. The total length of the OARSMT 210 is determined by summing the lengths of the horizontal and vertical segments constituting the tree. By leveraging the deep learning model 208, the system 200 can rapidly and efficiently estimate the length without resorting to computationally intensive heuristic methods traditionally used to solve the NP-complete OARSMT problem.

The integration of the encoding process and the deep learning model 208 enables the system 200 to provide rapid and accurate length of wire estimations. The capability is particularly advantageous during the placement phase of VLSI physical design, where rapid assessments of length of wires are crucial for optimizing component placement and minimizing overall circuit area and delay. The system 200 addresses the challenges associated with large routing grids and the presence of obstacles by reducing the complexity of the input data and employing a streamlined deep learning architecture.

FIG. 3 illustrates a wired circuit 300 using convolutional neural networks (CNNs) to predict the length of an OARSMT required to connect multiple pins 304, 306-1, and 306-2. The wired circuit 300 includes a routing grid 302, represented as m×m grid, where m denotes the dimensions of the grid. The routing grid 302 is the structural foundation for placing and organizing the components of the circuit.

The circuit diagram of the routing grid 302 includes a plurality of components and a plurality of nets of pins. Each net of pins comprises a source pin 304 and one or more sink pins 306-1 and 306-2. The source pin 304 and the sink pins 306-1 and 306-2 are placed on the routing grid 302. The plurality of components, which may include obstacles 308, represent obstacles to placing wiring. The obstacles 308 are physical barriers, such as pre-routed wires or other elements that obstruct direct routing paths and must be avoided during the wiring process. To wire the circuit with a minimum length of wire, an encoding technique is implemented to transform the circuit diagram into numerical data suitable for processing by a deep learning model, alternatively referred as to a deep neural network 324. A first data encoder 312 is configured to encode, based on the circuit diagram, an m×m pin image. The first encoding process includes placing a one at each pin location on a first routing grid and a zero at each location on the first routing grid that does not include a pin. The first encoding results in an m×m pin image representing the positions of the pins on the routing grid 302.

The wired circuit 300 further includes a second data encoder 314 configured to encode, based on the circuit diagram, an m×m obstacle image. The second encoding process includes placing ones at locations on a second routing grid that represent an obstacle 308 and zeros at each location on the second routing grid that does not include the obstacle 308. The second encoding process results in an m×m obstacle image representing the positions of the obstacles 308 on the routing grid 302.

To process the encoded images and reduce computational complexity, a series of transformations is applied to resize the images while preserving essential features of the image. A first Gaussian filtering is applied to the m×m pin image using a first Gaussian filter 316. The first Gaussian filter 316 and a first average pooling layer 320 is configured to resize the m×m pin image to form an m′×m′ pin image, where m′<<m. A second Gaussian filter 318 and a second average pooling layer 322 is configured to resize the m×m obstacle image to form an m′×m′ obstacle image, where m′<<m.

The Gaussian filtering is performed with a standard deviation σ_{G} and a radius r_{G} to avoid the occurrence of aliasing while reducing the image size. Aliasing causes multiple pins or obstacles to appear as one, leading to data loss. The separability property of Gaussian filtering allows the two-dimensional (2D) Gaussian filtering to be efficiently implemented by applying one-dimensional (1D) Gaussian filtering successively in the horizontal and vertical directions.

The average pooling layers (320, 322) are applied to the filtered images to down sample them from m×m size to m′×m′. The first average pooling layer 320 and the second average pooling layer 322 are configured to perform average pooling with a kernel size of (K_{G}×K_{G}) and a stride size of K_{G}. The pooling reduces the dimensions of the images while preserving the spatial information regarding the pins and obstacles.

The time complexity of the encoding method is determined by the operations involved. The 1D Gaussian filtering has a time complexity of O(m·r_{G}) due to the convolution operation over the image with radius r_{G}. The average pooling process has a time complexity of

$$O ( m \cdot \frac{m}{{m}^{′}} ) or O ( \frac{{m}^{2}}{{m}^{′}} ) ,$$

as it processes the entire image with a reduction factor based on the new dimensions m′. Therefore, the total time complexity of the image encoding step is O(m+m²) or O(m²), which is acceptable given the significant reduction in input size for the neural network.

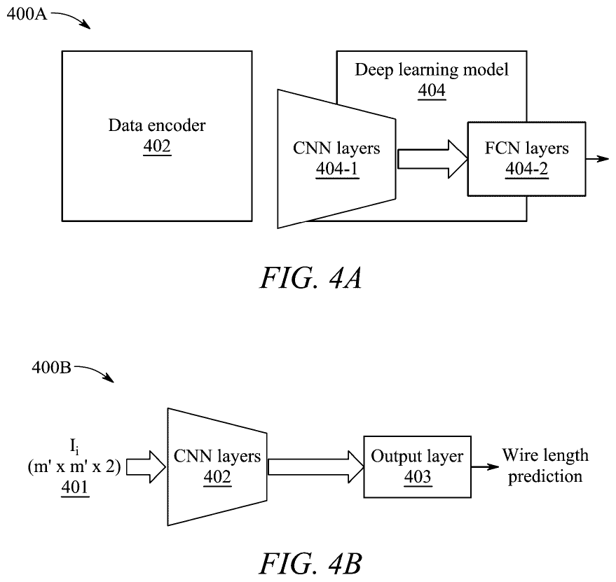

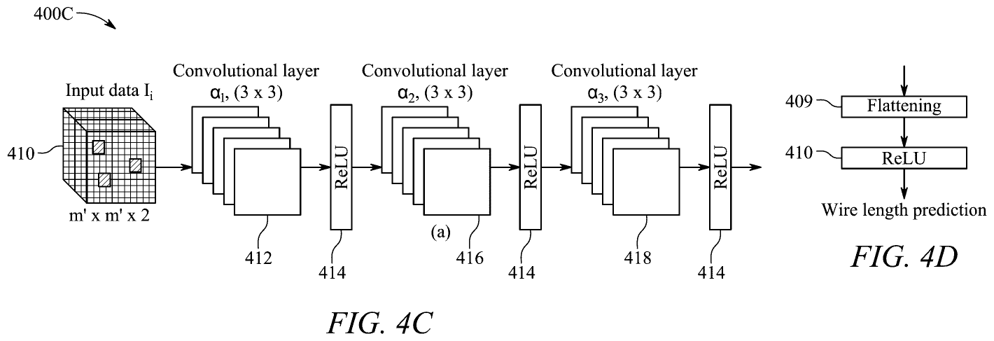

Referring both to FIG. 3 and FIG. 4A-4C, the resized m′×m′ pin image and the m′×m′ obstacle image are then input to a deep neural network 324 comprising a series of three convolutional neural network layers. The deep neural network 324 used for predicting length of wires in OARSMT routing relies on neural network architectures, particularly convolutional neural networks (CNNs), to manage the inherent complexities of integrated circuit design. The transforms high-dimensional circuit data, including pin and obstacle layouts, deep neural network 324 into a format suitable for deep learning processing. Thus, the wired circuit 300 predicts length of wires efficiently, even in the presence of obstacles 308, without solving the NP-complete OARSMT problem directly.

The first convolutional neural network layer has a kernel size of 3×3 and α₁ filters. The α₁ filters are configured to process the resized images to extract features related to the pins 304, 306-1, and 306-2 and the obstacles 308. As shown in FIG. 4C, a rectified linear unit (ReLU) activation layer follows each convolutional layer to introduce non-linearity and enable the network to learn complex patterns.

In one aspect, the first convolutional layer 412 uses α₁=64 filters, the second convolutional layer 416 uses α₂=32 filters, and the third convolutional layer 418 uses α₃=8 filters. Each layer applies convolution operations to the feature maps from the previous layer, progressively distilling the essential features needed to predict the OARSMT length.

An output layer 326 receives the output series of feature maps from the convolutional layers. The output layer 326 includes a flattening block that converts the multi-dimensional feature maps into a one-dimensional column array suitable for input into a fully connected layer or regression function. The ReLU block processes the flattened data to predict the OARSMT length of wire needed to connect each net of pins.

The predicted OARSMT length represents the minimum length of wire required to connect the source pin and sink pins without intersecting any obstacles. This prediction is achieved without explicitly solving the NP-complete OARSMT problem, thereby significantly reducing computational complexity and time. In one example, the system predicts the OARSMT length within a mean runtime of 15 milliseconds.

A computing device receives the OARSMT lengths of each of the nets of pins and estimates the minimum length of wire needed to connect all of the nets of pins. The computing device includes circuitry, a memory including program instructions and a placement algorithm (also referred to as a placer), and at least one processor configured to execute the program instructions the generate a wiring layout using the minimum length of wire.

A wire router 328 is configured to connect each of the nets of pins by the respective minimum length of wire, forming the wired circuit. The wire router 328 utilizes the predicted length of wires to generate routing paths that adhere to design constraints, including obstacle 308 avoidance and minimal length of wire.

The process encodes the layout of the circuit into binary images. Each pin and obstacle in the layout are represented as a 1 on a binary m×m grid, while other grid locations are represented as 0. These binary images are fed into a series of convolutional layers designed to extract spatial patterns and features from the layout for predicting the optimal wire routing between pins.

FIG. 4A illustrates a system 400A for processing circuit data using a deep learning model 404, alternatively referred to as a deep neural network 404, to predict length of wires for obstacle avoidance rectilinear Steiner minimal tree (OARSMT) routing. The system includes a data encoder 402 and the deep learning model 404.

The data encoder 402 transforms the pin and obstacle information from the circuit diagram into binary m×m images. In these images, the pins and obstacles are represented by ones, while the rest of the grid locations are zeros. This binary representation simplifies the computational processing by converting the complex layout into a format suitable for neural network analysis. The encoded images are processed through Gaussian filtering layers to smooth the data, reduce noise, and enhance essential features such as pin positions and obstacle boundaries. With the preprocessing, the most relevant details are retained while unnecessary information is filtered out. After Gaussian filtering, the images undergo average pooling, which reduces the dimensionality of the images, decreasing the computational load on the neural network while preserving the critical spatial relationships. The process results in two m′×m′ images, containing the necessary pin and obstacle features for input into the deep learning model 404.

FIG. 4B illustrates an abstract structure of a system 400B for processing the circuit data using the deep learning model 404. The CNN layers 402 receive the encoded pin and obstacle images 401 and apply successive convolution operations to generate feature maps. Each convolution operation in the CNN layer 402 includes sliding a small filter or kernel over the input image, computing the dot product between the filter and the input data at each position. The result is a new feature map that highlights specific aspects of the input, such as edges or textures, which are relevant for wire routing. These feature maps are then passed to an output layer 403, which generates a prediction for the OARSMT length of wire. This prediction is based on the learned features from the convolutional and fully connected layers, allowing the system to provide an accurate estimate of the length of wire needed to connect the pins while avoiding obstacles.

The feature mapping is performed by the deep learning model, as described in FIG. 4A. Convolutional layers 402 form the deep learning model. The convolutional layers 402 perform convolutions on the input images using a set of learnable filters, alternatively known as kernels. Each filter slides across the input grid, performing element-wise multiplications to detect features, such as pin locations and obstacle boundaries. With convolution operation, the local spatial relationships in the grid are captured, such as how pins are positioned relative to each other and to obstacles. The resulting feature maps, which are the output of each convolutional layer, reflect the spatial patterns and allow the network to process the data more effectively.

In one aspect, using a plurality of filters per layer embedded within the convolutional layers, enables the network to capture different types of spatial information at various scales. For example, a smaller filter may detect the presence of individual pins, while a larger filter may capture broader patterns, such as the overall layout of obstacles. As the input data passes through successive convolutional layers, the feature maps become increasingly abstract, representing higher-level patterns that are crucial for determining the optimal routing.

In addition to the convolutional operations, the output from each convolutional layer is passed through an activation function to introduce non-linearity into the model. In one aspect, the activation function, a ReLU 414, is implemented. The ReLU 414 function outputs the input directly if it is positive, but outputs zero for any negative input. Such non-linear transformation ensures that the deep learning model can learn complex patterns in the data by introducing non-linearities into the learning process. The ReLU is particularly implemented in deep networks to mitigate the vanishing gradient problem, where gradients become too small during backpropagation, slowing or halting the learning process. By allowing gradients to flow more easily, ReLU accelerates convergence during training and helps the model capture more intricate relationships between the pins and obstacles.

After the convolutional layers and activation functions have processed the data, the feature maps are processed for down sampling through pooling layers. Pooling layers reduce the spatial dimensions of the feature maps, which serves two primary purposes, reducing computational complexity and enhancing ability of the network to generalize. In one example of the pooling operation, max pooling is utilized. In max pooling, a small window, for example, 2×2 or 3×3, slides across the feature map, and then selects the maximum value from a set of neighboring pixels, preserving the most important features while discarding less relevant details. The down sampling step reduces the size of the data and enables the network focus on higher-level, more abstract patterns that are essential for routing.

Once the data has been processed through the convolutional and pooling layers, the feature maps are flattened into a one-dimensional array. The flattened array is passed through fully connected layers, where each neuron is connected to every neuron in the preceding layer. Fully connected layers allow the network to learn global patterns across the entire circuit layout, combining the local features detected by the convolutional layers into a holistic understanding of the layout.

The output from the fully connected layers is then passed to the output layer 403, which predicts the length of wire required for routing the circuit. The prediction is based on the learned representations from the convolutional and fully connected layers. With the learned representations, the deep learning model predicts length of wires in a fraction of the time it would take traditional algorithms to solve the OARSMT problem.

In a non-limiting example, the deep learning model incorporates additional architectures, such as recurrent neural networks (RNNs) or long short-term memory (LSTM) networks, to process sequential data or maintain long-term dependencies in the layout. RNNs and LSTMs are implemented for tasks where the relationship between pins and obstacles is complex and requires consideration of the entire layout over multiple steps.

Regularization techniques, such as dropout layers and batch normalization may be employed to improve generalization of the model and prevent overfitting. Dropout layers randomly deactivate a subset of neurons during training, encouraging the network to learn more robust features. Batch normalization normalizes the output of each convolutional layer, rendering consistent ranges for activation values and improving the stability of the training process.

In one aspect, the deep learning model is trained using backpropagation, where weights of the model are updated based on the error between the predicted and actual length of wires. Various optimization algorithms, such as stochastic gradient descent (SGD), Adam, and RMSprop, may be used to accelerate convergence and improve performance of the deep learning model. With such optimization techniques, the deep learning model learns the optimal weights and filters for accurately predicting length of wires across a variety of circuit layouts.

In terms of hardware implementation, the deep learning model may be deployed on a range of hardware platforms, including graphics processing units (GPUs), field-programmable gate arrays (FPGAs), application-specific integrated circuits (ASICs), and digital signal processors (DSPs). The hardware accelerators enable faster training and inference times by parallelizing computations and efficiently managing memory. In some implementations, the system may be deployed in distributed cloud environments, where multiple accelerators communicate through buffers, enabling large-scale, high-speed processing for complex circuit designs.

FIG. 4C illustrates a process of the individual steps performed by each of the CNN layers during the processing of the input data 410. The input data 410 consists of an m′×m′×2 image, which contains the encoded pin and obstacle information. The first convolutional layer 412 applies filters of size 3×3 to the input data, with a specific number of filters, denoted as α₁, applied at this stage. The filters are designed to capture initial features, such as the position and boundaries of the pins and obstacles. After the convolution operation, the output is passed through the ReLU activation layer 414, which applies the non-linear activation function to the feature maps.

The deep learning model 404 processes the encoded images through multiple convolutional neural network (CNN) layers (412, 416, and 418). CNNs are designed to handle grid-like data structures, making them suitable for image processing tasks. The CNN layers (412, 416, and 418) convolve the input image 410 with various filters to extract high-level features, such as spatial relationships between the pins and obstacles. Each CNN layer applies a set of convolutional filters to the input, followed by a non-linear activation function, for example, the ReLU. The ReLU function sets all negative pixel values in the feature maps to zero, introducing non-linearity into the model and preventing the vanishing gradient problem that often affects traditional activation functions.

As the encoded pin and obstacle images progress through the CNN layers (412, 416, and 418), feature maps are generated at each stage, capturing various aspects of the input data. The feature maps abstract the layout of pins and obstacles, allowing the model to focus on the relevant features for length of wire prediction. After feature extraction by the CNN layers (412, 416, and 418), the resulting feature maps are passed through a series of fully connected (FCN) layers 404-2. These fully connected layers integrate the outputs from the CNN layers to generate the final prediction. The FCN layers perform a weighted summation of the extracted features, where the learned weights represent the contribution of each feature to the predicted length of wire for the OARSMT. The final prediction is generated based on this summation, providing an estimate of the optimal length of wire needed to connect the pins while avoiding obstacles.

The CNN model contains three convolutional layers (412, 416, and 418), each using filters of size 3×3. These filters are used because the data matrices are down sampled to small dimensions during the encoding process. Larger filters are either unsuitable or require extensive zero padding, increasing the data dimensions unnecessarily. The deep convolutional network is configured to learn latent features from the data while maintaining a balance between complexity and performance. The described framework of convolutional networks with multiple layers is configured to learn both local and latent features from the input data. The framework is consistent with well-established architectures, such as VGG16, which uses a 3×3 kernel with several convolutional layers. In one example, an inception network employs multiple layers, however, kernel sizes remain small, such as 1×1, 3×3, and 5×5. By utilizing small filters and a limited number of layers, the model is able to produce accurate predictions within the constraints of computational efficiency.

The deep CNN with three convolutional layers is configured to extract the necessary features for length of wire prediction. Each of these convolutional layers contains a specific number of filters, denoted as α₁, α₂, and α₃, respectively. The values of the filters (where i∈{1, 2, 3}) are determined experimentally, as lower values may result in underfitting, while higher values can lead to overfitting and increased training times. In massively parallel architectures, such as GPUs, the number of filters has minimal impact on runtime, allowing the model to maintain computational efficiency.

According to one aspect, the input data 410 already has smaller dimensions due to the encoding process, thus eliminating the need for pooling layers. Eliminating the pooling layers aligns with recent research that demonstrates pooling layers may not be essential for effective performance in deep CNNs, particularly when the input data is sufficiently down sampled.

The final output layer of the network uses the ReLU activation function to predict the length of wire. The ReLU function is chosen because it limits the predicted wire-length value between 0 and 1, which is consistent with the problem constraints. The ReLU activation function facilitates efficient learning by eliminating negative values and preserving important information throughout the network. Consequently, the deep learning model accurately predicts the length of wire required to connect the pins in the presence of obstacles without encountering the vanishing gradient problem commonly associated with other activation functions. The entire architecture is designed to provide accurate and computationally efficient predictions for the OARSMT length of wire in complex circuit layouts.

The data then passes through a second convolutional layer 416, which applies additional filters, denoted as α₂, to further refine the features extracted from the previous layer. By applying more filters, the second convolutional layer 416 enhances the ability of the model to detect more complex patterns in the data, such as the spatial arrangement of multiple pins and obstacles. The output from the second convolutional layer 416 is once again passed through a ReLU activation layer 414 to introduce non-linearity and prevent overfitting.

A third convolutional layer 418 applies a final set of filters, denoted as α₃, which extract the most abstract features needed for the final prediction.

FIG. 4D illustrates a flattening layer 409 implemented within the deep learning model. The output from the third convolutional layer 418 is passed through the flattening layer 409, which converts the multi-dimensional feature maps into a one-dimensional column array for further processing by the fully connected layers. The output layer produces the final prediction, which estimates the length of the wire needed to connect the pins through the OARSMT.

A computing device, which may be a part of the output layer or a separate computing device, estimates the minimum length of wire needed to connect all of the nets of pins. A placement algorithm (referred to as a placer) stored in the computing device generates a wiring layout using the minimum length of wire, and a wiring router connects each of the nets of pins with the minimum length of wire to form the wired circuit based on the wiring layout.

In the exemplary illustration, three convolution layers are implemented with specific input and output dimensions. Table I presents the input/output dimensions and the number of parameters for the three convolution layers, as described in FIG. 4C and FIG. 4D. The calculations were conducted under the assumption that the padding is zero and the stride is set to one. The expressions provided in the Table 1 demonstrate that the values of hyperparameters, along with the data dimensions in the encoding phase, are used in determining both the quality of the solution and the memory usage.

TABLE 1
Dimensions of data and number of parameters of various layers
of the model (kernel size = 3 × 3)

| Convolutional | | | |
|---|---|---|---|
| Layers | Input | Output | parameters |
| 1^{st} | m′ × m′ × 2 | (m′ − 2) × (m′ − 2) × α₁ | 19α₁ |
| 2^{nd} | (m′ − 2) × (m′ − 2) × α₁ | (m′ − 4) × (m′ − 4) × α₂ | α₂(9α₁ + 1) |
| 3^{rd} | (m′ − 4) × (m′ − 4) × α₂ | (m′ − 6) × (m′ − 6) × α3 | α₃(9α₂ + 1) |
| FC Layer | α₃(m′ − 6)² | 1 | α₃(m′ − 6)² + 1 |

The time complexity of the OARSMT heuristic was determined to be O(z³), z=x+4y, with x and y representing the number of pins and obstacles in the problem, respectively. The time complexity can be significant due to the large number of pins and obstacles encountered in practical scenarios. The method incorporates a Gaussian filter followed by three convolutional layers. The time complexity for Gaussian filtering using separable filters is O(m²) since Gaussian filtering involves convolution operations. The convolutional layer exhibits a time complexity of O(m′²), assuming a constant kernel size and the capability for simultaneous processing of all channels via parallel computing. Therefore, the overall time complexity of the method is O(m²), given that m>m′. The execution time remains constant as long as the dimensions of the routing grid do not change.

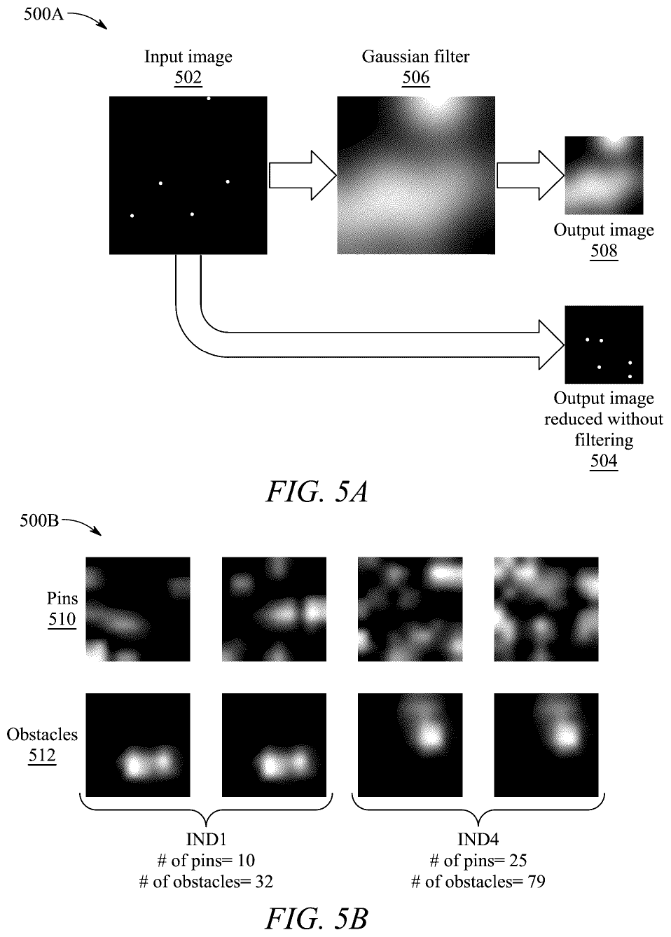

FIG. 5A is an exemplary illustration of a process of reducing the size of an input image 502 using Gaussian filtering and average pooling for OARSMT computation.

The input image 502 is a binary image of size 300×300, where white pixels represent the locations of pins on the routing grid. This input image contains five white pixels, which correspond to the pin positions. The size reduction process is performed with the application of Gaussian filtering, at step 506. The Gaussian filter uses a standard deviation of kernel (σ) equal to 50, in one example. Application of the Gaussian filter smooths the image maintain the attributes of features, such as pin positions, and are preserved while irrelevant noise is reduced. The resulting image is an intermediate representation that maintains the spatial relationships between the pins, despite the reduction in detail.

Following Gaussian filtering, the image undergoes average pooling, reducing the size of the image to 150×150. The output image 508 represents the result of this process, with a smaller size that retains sufficient information for accurate prediction of length of wires. In the reduced image, the essential features remain intact due to the Gaussian filtering application before resizing.

In contrast, output image 504, which depicts an attempt at reducing the image size without Gaussian filtering, shows almost complete information loss. Without filtering, the fine details related to pin positions are significantly degraded, leading to a loss of critical spatial information. This emphasizes the importance of applying Gaussian filtering prior to pooling when resizing images for OARSMT computation.

FIG. 5B illustrates the processed images of pin data 510 and obstacle data 512 used in the deep learning model for the OARSMT computation. The processed images represent resized and filtered versions of the original input images after undergoing Gaussian filtering and average pooling, as described in FIG. 5A.

The pin images 510 depict the locations of multiple pins in two separate examples: IND1, with 10 pins, and IND4, with 25 pins. Each pin location is represented as a bright spot within the image. The Gaussian filtering and pooling processes reduce the overall image size while retaining important pin information, allowing the neural network to extract the necessary features for predicting length of wire efficiently.

The obstacle images 512 depict the locations of obstacles corresponding to the pin images. The images in IND1 represent a configuration with 32 obstacles, while the images in IND4 represent a configuration with 79 obstacles. The obstacle data is encoded similarly to the pin data, with each obstacle location appearing as a bright region in the image.

The processed pin and obstacle images serve as input to the convolutional neural network layers, which use these feature maps to predict the length of wire required for the OARSMT. The processed data retains sufficient information to allow the deep learning model to account for both pin and obstacle positions while predicting the minimum length of wire needed to connect the pins without crossing obstacles.

Experiments were conducted using five industrial test cases (IND1-IND5) for placement, which were released by Synopsys and are widely used in physical design research. Each test case contained a distinct rectangular grid featuring obstacles and a set of terminals. Table 2 outlines the key characteristics of the test cases, with all grid sizes set to 1000-by-1000. Multiple samples were generated to form the training, validation, and test sets by randomly relocating the pins to different positions on the grid. The parameters of the test cases, such as obstacles, the number of pins, and grid size, remained unchanged. The length of wire of the OARSMT for each test problem was determined by solving the test problem using an OARSMT generation tool. For the test cases IND1-IND5, the training set contains between 68 K to 100 K samples, while the validation and test sets consist of 50 K samples.

The methods of the present disclosure were implemented using TensorFlow in Python and executed on a system with an Intel Xeon 2.8 GHz processor and an Nvidia Tesla 4 GPU. Hyperparameters used in the present disclosure are set as: m′=10, σ_{G}=100, r_{G}=100, α₁=64, α₂=32, α₃=8, and β=7. The training parameters were set as follows: hyperparameters as follows: optimizer=Adam, loss function=MSE, learning rate=le⁴, training epochs=2000, steps per epoch=50, and batch size=32.

TABLE 2
Features of the test cases

| Test case | Number of pins | # of obstacles |
|---|---|---|
| IND1 | 10 | 32 |
| IND2 | 10 | 43 |
| IND3 | 10 | 50 |
| IND4 | 25 | 79 |
| IND5 | 33 | 71 |

The values of the hyperparameters were determined through experimentation with multiple alternatives, selecting the ones that did not result in either under-fitting or over-fitting. The data matrix size of m′×m′ was selected to ensure that the data remained low-dimensional, allowing the deep learning models to generate accurate predictions. A large value of m′ not only increase memory requirements but also adds complexity to the deep learning model. Without down-sampling the data to smaller dimensions, the number of parameters in the model equals 32×10⁹, whereas down-sampling to m′×m′=10×10 reduces the number of parameters to 8.5×10⁵. The parameters σ_{G}=100 and r_{G}=100 were chosen as they minimized the zero values in the encoded images.

The performance of the method of the present disclosure was compared with three existing methods: a neural network (NN) with one hidden layer (NN1), the LeNet-5 model with a filter size of 3×3 (LeNet5 architecture), and a linear regression model that utilizes the relationship between the convex hull (CHULL) of the pins and the length of wire (LR_CHULL). The NN1 model includes 512 hidden layers and uses the ReLU activation function. LeNet-5, a widely used model for image classification, has two convolutional layers and two fully connected layers and employs ReLU activation. In the present disclosure, the softmax layer in LeNet-5 was replaced with a single-output ReLU layer to handle the regression task. The filter size was adjusted to 3×3 from 5×5 to accommodate the data dimensions used (10×10). Although more recent CNN models have been developed, they were deemed unsuitable due to their larger number of layers or their design for relatively larger images. The CHULL feature was extracted from the data and a linear regression was used to predict length of wire (LR_CHULL). The linear regression was implemented, and training data was used to compute the slope and y-intercept. The linear regression model was also employed to predict the OARSMT's length of wire for the test data.

For runtime measurement, the model, LeNet-5, and NN1 were executed on a Nvidia Tesla T4 GPU, while the OARSMT's heuristic and LR_CHULL were executed on an Intel Xeon 2.8 GHz processor. The experimental results demonstrated that the runtime of the model varied between 0.015 seconds to 0.017 seconds, with a mean runtime of 0.015 seconds. The OARSMT's heuristic had a runtime between 0.07 seconds to 0.88 seconds, with a mean of 0.21 seconds. The average execution times for LeNet-5, NN1, and LR_CHULL were 0.018 seconds, 0.010 seconds, and 0.002 seconds, respectively. The runtime of LR_CHULL is small because the prediction using linear regression only involves a single multiplication operation. The OARSMT's heuristic exhibited the longest runtime. The results indicate that the runtime to make a prediction is 15 ms, making it suitable for real-time operations and significantly faster than the 210 ms runtime of the OARSMT heuristic. Although LR_CHULL is the fastest, its prediction accuracy is shown to be inferior in subsequent analyses.

TABLE 3
Bias and variance results of the present
and other models on the problem IND1

| | Error | | |
|---|---|---|---|
| Model | Training | Validation | Remarks |
| NN1 | 1.45e⁻⁵ | 132.48e⁻⁵ | Low bias and high variance |
| LeNet5 | 183.66e⁻⁵ | 192.72e⁻⁵ | High bias and low-variance |
| Present | 76.10e⁻⁵ | 99.63e⁻⁵ | Balance between bias and variance |
| Application | | | |

Table 3 presents the error rates for the model and other methods on both the training and validation sets. The results for NN1 demonstrate a very low error rate (1.45×10⁻⁵) on the training set but a significantly higher error rate (132.48×10⁻⁵) on the test set. The error on the test set is 90 times greater than on the training set, indicating that the model exhibits low bias (a very small training error) and high variance (a large discrepancy between the test error and the training error). The error rates for LeNet5 show that it has low variance (a small difference between the training and validation sets) but exhibits high bias (a higher training error). In contrast, the model demonstrates a balance between bias and variance, as the training error is not excessively high, and the test error is closer to the training error. The errors observed in the training and validation sets for the problems IND2-IND5 follow a pattern similar to IND1 and are not included here for the sake of brevity.

The prediction accuracy of the model and other approaches was assessed by calculating the absolute difference between the predicted length of wire and the actual length of wire on the test set, known as the residual. Table IV displays the lower quartile (25%), mean (50%), and upper quartile (75%) of the residuals for the four models. The data indicates that the upper quartile for the method is 77.70, 107.02, 76.45, 109.73, and 114.054 for problems IND1-IND4, respectively. The upper quartiles for LeNet5, NN1, and LR_CHULL are higher than those observed for the method, signifying that the method offers greater accuracy compared to its competitors.

The present disclosure presents a deep learning-based (DL-based) system for the rapid prediction of the length of the OARSMT for any set of pins. The capability to predict length of wire rapidly is essential in the VLSI physical placement task, as it facilitates the use of OARSMT's length as a length of wire estimation when the routing grid contains obstacles. The first component of the system encodes the problem data and represents it using two small-sized images. In the subsequent step, a DL model, comprising convolutional layers, is employed to predict the OARSMT's length. The encoding step efficiently reduces the dimensionality of the problem data, allowing the use of a DL model with fewer parameters. The DL model consists of three convolutional layers followed by an output layer. The training, validation, and testing sets were generated using industrial test problems provided by Synopsys, 675 Almanor Ave Sunnyvale, CA, United States of America 94085.

In experimental evaluations, the system produced predictions with mean residuals of 59, 79, 54, 77, and 79 across different test problems. The experimental results demonstrated that the system is both fast and accurate, outperforming alternative approaches, including a neural network with a hidden layer, LeNet-5, and linear regression models based on manually extracted features. The system may require training on the same routing grid used during placement. In aspects, the application of this method is envisioned in actual placement tools.

The present disclosure as described through FIG. 1A to FIG. 5B, in accordance with some aspects, discloses a method for wiring a circuit with a minimum length of wire. The method includes obtaining a circuit diagram of the circuit. The circuit diagram includes a plurality of components and a plurality of nets of pins. Each net of pins comprises a source pin and one or more sink pins. Each of the plurality of components are obstacles to placing wiring. The method further includes encoding, based on the circuit diagram, an m×m pin image by placing a one at each pin location on a first routing grid and a zero at each location on the first routing grid which does not include a pin, and encoding, based on the circuit diagram, an m×m obstacle image by placing ones at locations on a second routing grid which represent an obstacle and a zero at each location on the second routing grid which does not include the obstacle. The method further includes resizing the m×m pin image to form an m′×m′ pin image, where m′ <<m, resizing the m×m obstacle image to form an m′×m′ obstacle image, where m′<<m, generating an output series of feature maps by applying the m′×m′ pin image and the m′×m′ obstacle image to a series of three convolutional neural network layers, applying the output series of feature maps to an output layer, predicting, by the output layer, an obstacle avoidance rectilinear Steiner minimal tree (OARSMT) length of wire needed to connect each net of pins, estimating the minimum length of wire needed to connect all of the nets of pins; generating, with a placer, a wiring layout using the minimum length of wire; and connecting, with a wiring router, each of the nets of pins with the minimum length of wire to form the wired circuit based on the wiring layout.

In one aspect, resizing the m×m pin image comprises applying Gaussian filtering with a standard deviation of σ_{G} and a radius of r_{G}, and down sampling the first m×m image by applying average pooling with a kernel size of K_{G}×K_{G} and a stride size of K_{G}.

In one aspect, resizing the m×m obstacle image comprises applying Gaussian filtering with a standard deviation of σ_{G} and a radius of r_{G} and down sampling the second m×m image by applying average pooling with a kernel size of K_{G}×K_{G} and a stride size of K_{G}.

In one aspect, m equals 300, m′ equals 10, σ_{G} equals 100, r_{G} equals 100 and K_{G} equals 3.

In one aspect, predicting, by the output layer, the OARSMT length needed to connect the pins comprises converting, by a flattening block, each feature map into a column array and applying each column array to an output layer rectified linear unit (ReLU) block, and generating, by the output layer ReLU block, the OARSMT length.

In one aspect, the method further includes predicting the OARSMT length within a mean runtime of 15 ms.

In one aspect, applying the m′×m′ pin image and the m′×m′ obstacle image to a series of three convolutional neural network layers further comprises applying the m′×m′ pin image and the m′×m′ obstacle image to a first convolutional neural network layer of the series of three convolutional neural network layers. The first convolutional neural network layer has a kernel size of 3×3 and α₁ filters. The applying the m′×m′ pin image and the m′×m′ obstacle image to a series of three convolutional neural network layers further comprises filtering, by the α₁ filters, the m′×m′ pin image and the m′×m′ obstacle image to isolate images having pin features and obstacle features, applying the images having pin features and obstacle features to a first ReLu activation layer to detect a first set of pin features and obstacle features, and generating, by the first ReLu activation layer, a first set of feature maps based on the first set of pin features and obstacle features.

In one aspect, α₁ equals 64.

In one aspect, the method includes applying the first set of feature maps to a second convolutional neural network layer of the series of three convolutional neural network layers. The second convolutional neural network layer has a kernel size of 3×3 and α₂ filters. The method further includes filtering, by α₂ filters, the first set of feature maps to isolate to isolate images having the pin features and obstacle features, applying the images having the pin features and obstacle features to a second ReLu activation layer to detect a second set of pin features and obstacle features, and generating, by the second ReLu activation layer, a second set of feature maps based on the first set and the second set of pin features and obstacles features.

In one aspect, α₂ equals 32.

In one aspect, the method includes applying the second set of feature maps to a third convolutional neural network layer of the series of three convolutional neural network layers. The third convolutional neural network layer has a kernel size of 3×3 and α₃ filters. The method further includes filtering, by the α₃ filters, the second set of feature maps to isolate images having pin features and obstacle features, applying the images having pin features and obstacle features to a third ReLu activation layer to detect a third set of pin features and obstacle features, and generating the output series of feature maps based on the first, second and third sets of pin features and obstacles features.

In one aspect, α₃ equals 8.

In one aspect, the method includes calculating the OARSMT length as a minimum length of wire needed to connect the net of pins without running the wire through the obstacles during wire routing.

In another embodiment of the present disclosure a wired circuit is disclosed. The wired circuit includes a circuit diagram including a plurality of components and a plurality of nets of pins. Each net of pins comprises a source pin and one or more sink pins, and each of the plurality of components are obstacles to placing wiring. The wired circuit further includes a first data encoder configured to encode, based on the circuit diagram, an m×m pin image by placing a one at each pin location on a first routing grid and a zero at each location on the first routing grid which does not include a pin and a second data encoder configured to encode, based on the circuit diagram, an m×m obstacle image by placing ones at locations on a second routing grid which represent an obstacle and a zero at each location on the second routing grid which does not include the obstacle. The wired circuit further includes a first Gaussian filter, and a first average pooling layer configured to resize the m×m pin image to form an m′×m′ pin image, where m′<<m, a second Gaussian filter and a second average pooling layer configured to resize the m×m obstacle image to form an m′×m′ obstacle image, where m′<<m. The wired circuit further include a series of three convolutional neural network layers configured to receive the m′×m′ pin image and the m′×m′ obstacle image and generate an output series of feature maps an output layer configured to receive the output series of feature maps and predict an obstacle avoidance rectilinear Steiner minimal tree (OARSMT) length of wire needed to connect each net of pins, and a computing device configured to estimate the minimum length of wire needed to connect all of the nets of pins, a placer configured to generate a wiring layout using the minimum length of wire, and a wiring router configured to connect each of the nets of pins with the minimum length of wire to form the wired circuit based on the wiring layout.

In one aspect, the first Gaussian filter is configured to apply Gaussian filtering with a standard deviation of σ_{G} and a radius of r_{G}, the first average pooling layer has a kernel size of K_{G}×K_{G} and a stride size of K_{G}, the second Gaussian filter is configured to apply Gaussian filtering with a standard deviation of σ_{G} and a radius of r_{G}, and the second average pooling layer has a kernel size of K_{G}×K_{G} and a stride size of K_{G}.

In one aspect, the series of three convolutional neural network layers further comprises a first convolutional neural network layer which has a kernel size of 3×3 and α₁ filters, where the α₁ filters are configured to filter the m′×m′ pin image and the m′×m′ obstacle image to isolate images having pin features and obstacle features, and a first ReLu activation layer configured to detect a first set of pin features and obstacle features in the isolated images and generate a first set of feature maps based on the first set of pin features and obstacle features.

In one aspect, the series of three convolutional neural network layers further comprises a second convolutional neural network layer which has a kernel size of 3×3 and α₂ filters, where the α₂ filters are configured to filter the first set of feature maps to isolate images having pin features and obstacle features, and a second ReLu activation layer configured to detect a second set of pin features and obstacle features in the isolated images and generate a second set of feature maps based on the first set and the second set of pin features and obstacle features.

In one aspect, the series of three convolutional neural network layers further comprises a third convolutional neural network layer which has a kernel size of 3×3 and α₃ filters, where the α₃ filters are configured to filter the second set of feature maps to isolate images having a third set of pin features and obstacle features, and a third ReLu activation layer configured to detect a third set of pin features and obstacle features in the isolated images and generate the output series of feature maps based on the first, second and third sets of pin features and obstacles features.

In one aspect, m equals 300, m′ equals 10, σ_{G} equals 100, IG equals 100 and K_{G} equals 3, α₁ equals 64, α₂ equals 32 and α₃ equals 8.

In one aspect, the wired circuit further includes a flattening block included in the output layer, where the flattening block is configured to convert each feature map into a column array, an output layer rectified linear unit (ReLU) block configured to receive the column array and predict the OARSMT length.

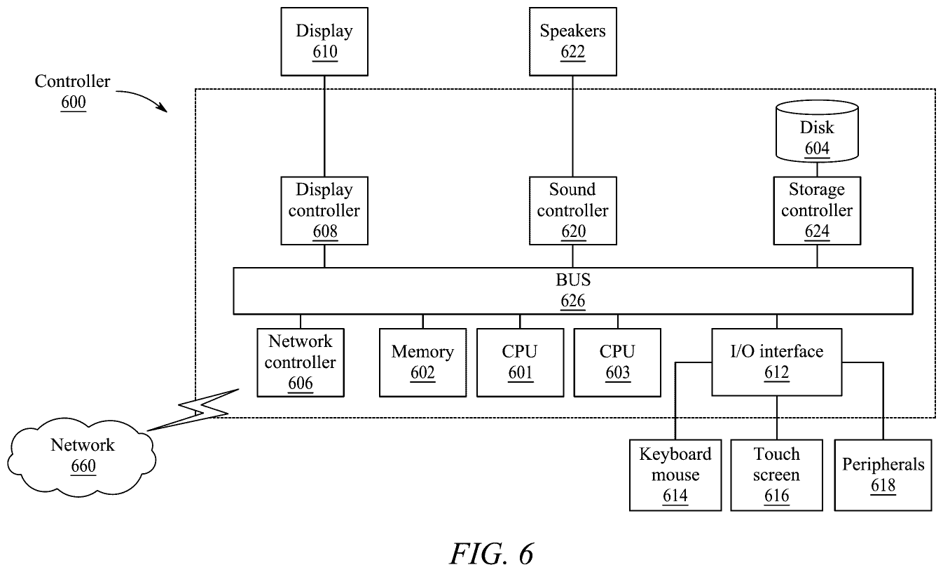

Next, further details of the hardware description of the computing environment according to exemplary embodiments are described with reference to FIG. 6. In FIG. 6, a controller 600 is described as representative of the system 300 of FIG. 3 in which the controller is a computing device which includes a CPU 601 which performs the processes described above/below. The process data and instructions may be stored in memory 602. These processes and instructions may also be stored on a storage medium disk 604 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 601, 603 and an operating system such as Microsoft Windows 7, Microsoft Windows 8, Microsoft Windows 11, UNIX, Solaris, LINUX, Apple MAC-OS and other systems known to those skilled in the art.

The hardware elements in order to achieve the computing device may be realized by various circuitry elements, known to those skilled in the art. For example, CPU 601 or CPU 603 may be a Xenon or Core processor from Intel of America or an Opteron processor from AMD of America, or may be other processor types that would be recognized by one of ordinary skill in the art. Alternatively, the CPU 601, 603 may be implemented on an FPGA, ASIC, PLD or using discrete logic circuits, as one of ordinary skill in the art would recognize. Further, CPU 601, 603 may be implemented as multiple processors cooperatively working in parallel to perform the instructions of the inventive processes described above.

The computing device in FIG. 6 also includes a network controller 606, such as an Intel Ethernet PRO network interface card from Intel Corporation of America, for interfacing with network 660. As can be appreciated, the network 660 can be a public network, such as the Internet, or a private network such as an LAN or WAN network, or any combination thereof and can also include PSTN or ISDN sub-networks. The network 660 can also be wired, such as an Ethernet network, or can be wireless such as a cellular network including EDGE, 3G, 4G and 5G wireless cellular systems. The wireless network can also be WiFi, Bluetooth, or any other wireless form of communication that is known.

The computing device further includes a display controller 608, such as a NVIDIA GeForce GTX or Quadro graphics adaptor from NVIDIA Corporation of America for interfacing with display 610, such as a Hewlett Packard HPL2445w LCD monitor. A general purpose I/O interface 612 interfaces with a keyboard and/or mouse 614 as well as a touch screen panel 616 on or separate from display 610. General purpose I/O interface also connects to a variety of peripherals 618 including printers and scanners, such as an OfficeJet or DeskJet from Hewlett Packard.

A sound controller 620 is also provided in the computing device such as Sound Blaster X-Fi Titanium from Creative, to interface with speakers/microphone 622 thereby providing sounds and/or music.

The general purpose storage controller 624 connects the storage medium disk 604 with communication bus 626, which may be an ISA, EISA, VESA, PCI, or similar, for interconnecting all of the components of the computing device. A description of the general features and functionality of the display 610, keyboard and/or mouse 614, as well as the display controller 608, storage controller 624, network controller 606, sound controller 620, and general purpose I/O interface 612 is omitted herein for brevity as these features are known.

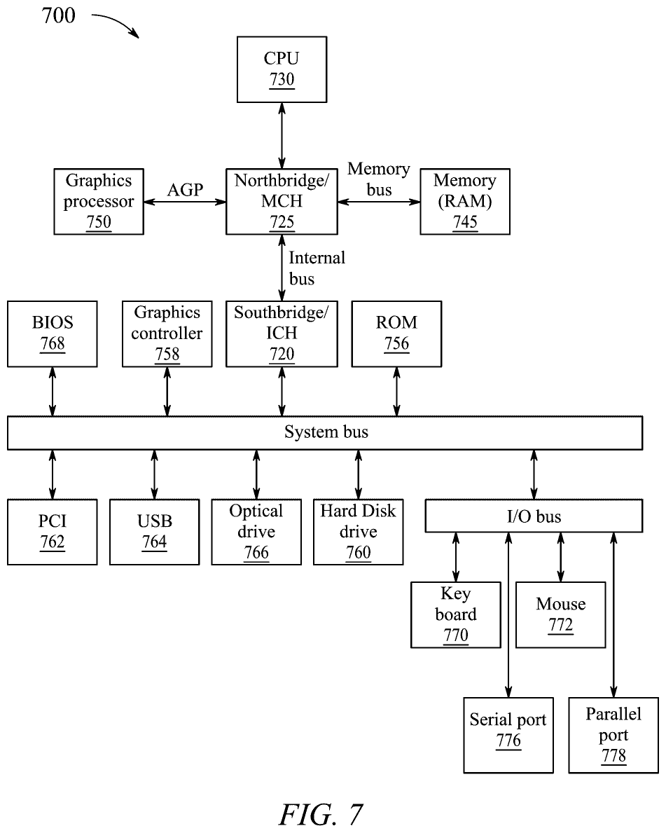

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 7.

FIG. 7 shows a schematic diagram of a data processing system, according to certain embodiments, for performing the functions of the exemplary embodiments. The data processing system is an example of a computer in which code or instructions implementing the processes of the illustrative embodiments may be located.

In FIG. 7, data processing system 700 employs a hub architecture including a north bridge and memory controller hub (NB/MCH) 725 and a south bridge and input/output (I/O) controller hub (SB/ICH) 720. The central processing unit (CPU) 730 is connected to NB/MCH 725. The NB/MCH 725 also connects to the memory 745 via a memory bus, and connects to the graphics processor 750 via an accelerated graphics port (AGP). The NB/MCH 725 also connects to the SB/ICH 720 via an internal bus (e.g., a unified media interface or a direct media interface). The CPU Processing unit 730 may contain one or more processors and even may be implemented using one or more heterogeneous processor systems.

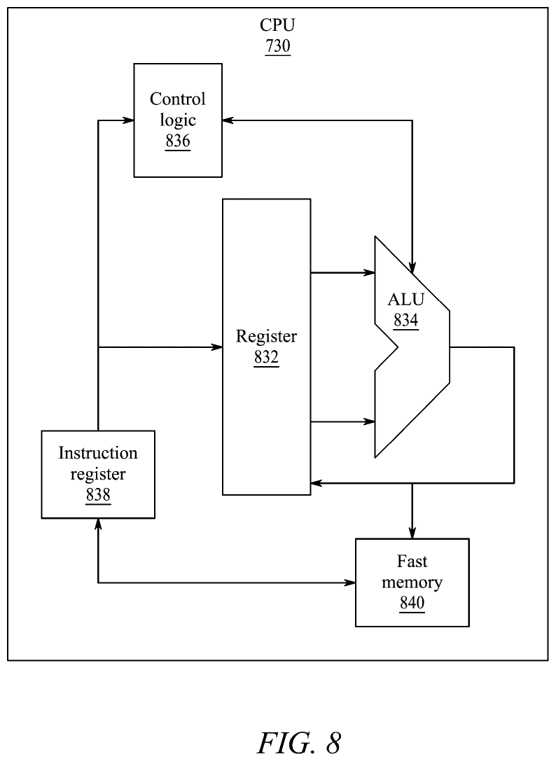

For example, FIG. 8 shows one implementation of CPU 730. In one implementation, the instruction register 838 retrieves instructions from the fast memory 840. At least part of these instructions are fetched from the instruction register 838 by the control logic 836 and interpreted according to the instruction set architecture of the CPU 730. Part of the instructions can also be directed to the register 832. In one implementation the instructions are decoded according to a hardwired method, and in another implementation the instructions are decoded according a microprogram that translates instructions into sets of CPU configuration signals that are applied sequentially over multiple clock pulses. After fetching and decoding the instructions, the instructions are executed using the arithmetic logic unit (ALU) 834 that loads values from the register 832 and performs logical and mathematical operations on the loaded values according to the instructions. The results from these operations can be feedback into the register and/or stored in the fast memory 840. According to certain implementations, the instruction set architecture of the CPU 730 can use a reduced instruction set architecture, a complex instruction set architecture, a vector processor architecture, a very large instruction word architecture. Furthermore, the CPU 730 can be based on the Von Neuman model or the Harvard model. The CPU 730 can be a digital signal processor, an FPGA, an ASIC, a PLA, a PLD, or a CPLD. Further, the CPU 730 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 7, the data processing system 700 can include that the SB/ICH 720 is coupled through a system bus to an I/O Bus, a read only memory (ROM) 756, universal serial bus (USB) port 764, a flash binary input/output system (BIOS) 768, and a graphics controller 758. PCI/PCIe devices can also be coupled to SB/ICH 788 through a PCI bus 762.

The PCI devices may include, for example, Ethernet adapters, add-in cards, and PC cards for notebook computers. The Hard disk drive 760 and CD-ROM 766 can use, for example, an integrated drive electronics (IDE) or serial advanced technology attachment (SATA) interface. In one implementation the I/O bus can include a super I/O (SIO) device.

Further, the hard disk drive (HDD) 760 and optical drive 766 can also be coupled to the SB/ICH 720 through a system bus. In one implementation, a keyboard 770, a mouse 772, a parallel port 778, and a serial port 776 can be connected to the system bus through the I/O bus. Other peripherals and devices that can be connected to the SB/ICH 720 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

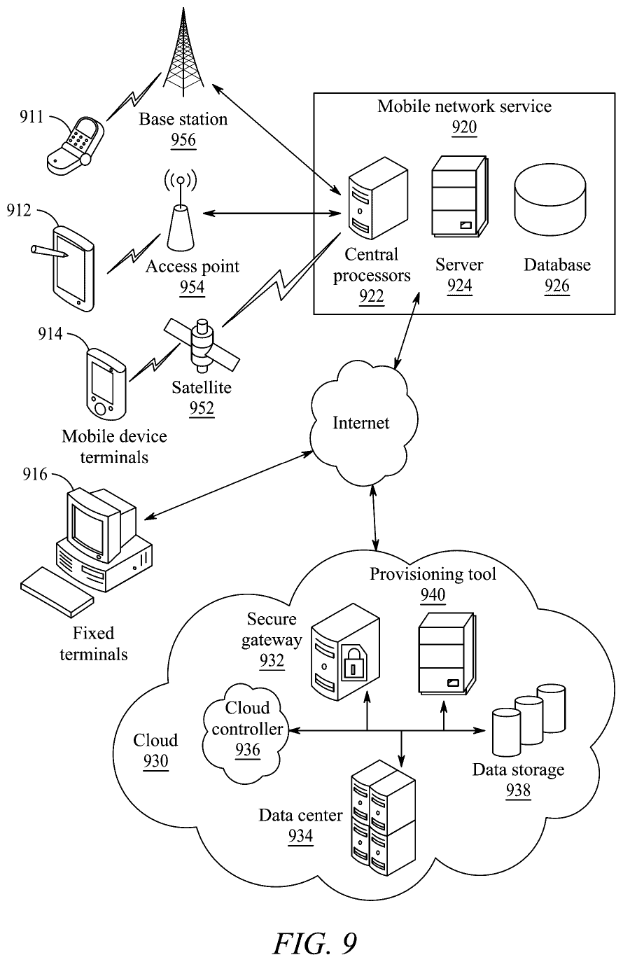

The functions and features described herein may also be executed by various distributed components of a system. For example, one or more processors may execute these system functions, wherein the processors are distributed across multiple components communicating in a network. The distributed components may include one or more client and server machines, such as cloud 930 including a cloud controller 936, a secure gateway 932, a data center 934, data storage 938 and a provisioning tool 940, and mobile network services 920 including central processors 922, a server 924 and a database 926, which may share processing, as shown by FIG. 9, in addition to various human interface and communication devices (e.g., display monitors 916, smart phones 910, tablets 912, personal digital assistants (PDAs) 914). The network may be a private network, such as a LAN, satellite 952 or WAN 954, or be a public network, may such as the Internet. Input to the system may be received via direct user input and received remotely either in real-time or as a batch process. Additionally, some implementations may be performed on modules or hardware that are not identical to those described. Accordingly, other implementations are within the scope that may be claimed.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A method for wiring a circuit with a minimum length of wire, comprising:
obtaining a circuit diagram of the circuit, wherein the circuit diagram includes a plurality of components and a plurality of nets of pins, wherein each net of pins comprises a source pin and one or more sink pins, and wherein each of the plurality of components are obstacles to placing wiring;
encoding, based on the circuit diagram, an m×m pin image by placing a one at each pin location on a first routing grid and a zero at each location on the first routing grid which does not include a pin;
encoding, based on the circuit diagram, an m×m obstacle image by placing ones at locations on a second routing grid which represent an obstacle and a zero at each location on the second routing grid which does not include the obstacle;
resizing the m×m pin image to form an m′×m′ pin image, where m′<<m;
resizing the m×m obstacle image to form an m′×m′ obstacle image, where m′<<m;
generating an output series of feature maps by applying the m′×m′ pin image and the m′×m′ obstacle image to a series of three convolutional neural network layers;
applying the output series of feature maps to an output layer;
predicting, by the output layer, an obstacle avoidance rectilinear Steiner minimal tree (OARSMT) length of wire needed to connect each net of pins;
estimating the minimum length of wire needed to connect all of the nets of pins; and
generating, with a placer, a wiring layout using the minimum length of wire;
connecting, with a wiring router, each of the nets of pins with the minimum length of wire to form the wired circuit based on the wiring layout.

2. The method of claim 1, wherein resizing the m×m pin image comprises:
applying Gaussian filtering with a standard deviation of σ_{G} and a radius of r_{G}; and
down sampling the first m×m image by applying average pooling with a kernel size of K_{G}×K_{G} and a stride size of K_{G}.

3. The method of claim 2, wherein resizing the m×m obstacle image comprises:
applying Gaussian filtering with a standard deviation of σ_{G} and a radius of r_{G}; and
down sampling the second m×m image by applying average pooling with a kernel size of K_{G}×K_{G} and a stride size of K_{G}.

4. The method of claim 3, wherein m equals 300, m′ equals 10, σ_{G} equals 100, IG equals 100 and K_{G} equals 3.

5. The method of claim 1, wherein predicting, by the output layer, the OARSMT length needed to connect the pins comprises converting, by a flattening block, each feature map into a column array and applying each column array to an output layer rectified linear unit (ReLU) block, and generating, by the output layer ReLU block, the OARSMT length.

6. The method of claim 5, further comprising:
predicting the OARSMT length within a mean runtime of 15 ms.

7. The method of claim 1, wherein applying the m′×m′ pin image and the m′×m′ obstacle image to a series of three convolutional neural network layers further comprises:
applying the m′×m′ pin image and the m′×m′ obstacle image to a first convolutional neural network layer of the series of three convolutional neural network layers, wherein the first convolutional neural network layer has a kernel size of 3×3 and α₁ filters;
filtering, by the α₁ filters, the m′×m′ pin image and the m′×m′ obstacle image to isolate images having pin features and obstacle features; and
applying the images having pin features and obstacle features to a first ReLu activation layer to detect a first set of pin features and obstacle features; and
generating, by the first ReLu activation layer, a first set of feature maps based on the first set of pin features and obstacle features.

8. The method of claim 7, wherein α₁ equals 64.

9. The method of claim 8, further comprising:
applying the first set of feature maps to a second convolutional neural network layer of the series of three convolutional neural network layers, wherein the second convolutional neural network layer has a kernel size of 3×3 and α₂ filters;
filtering, by α₂ filters, the first set of feature maps to isolate to isolate images having the pin features and obstacle features; and
applying the images having the pin features and obstacle features to a second ReLu activation layer to detect a second set of pin features and obstacle features; and
generating, by the second ReLu activation layer, a second set of feature maps based on the first set and the second set of pin features and obstacles features.

10. The method of claim 9, wherein α₂ equals 32.

11. The method of claim 10, further comprising:
applying the second set of feature maps to a third convolutional neural network layer of the series of three convolutional neural network layers, wherein the third convolutional neural network layer has a kernel size of 3×3 and α₃ filters;
filtering, by the α₃ filters, the second set of feature maps to isolate images having pin features and obstacle features;
applying the images having pin features and obstacle features to a third ReLu activation layer to detect a third set of pin features and obstacle features; and
generating the output series of feature maps based on the first, second and third sets of pin features and obstacles features.

12. The method of claim 11, wherein α₃ equals 8.

13. The method of claim 1, further comprising:
calculating the OARSMT length as a minimum wire length needed to connect the net of pins without running the wire through the obstacles during wire routing.

14. A wired circuit, comprising:
a circuit diagram including a plurality of components and a plurality of nets of pins, wherein each net of pins comprises a source pin and one or more sink pins, and wherein each of the plurality of components are obstacles to placing wiring;
a first data encoder configured to encode, based on the circuit diagram, an m×m pin image by placing a one at each pin location on a first routing grid and a zero at each location on the first routing grid which does not include a pin;
a second data encoder configured to encode, based on the circuit diagram, an m×m obstacle image by placing ones at locations on a second routing grid which represent an obstacle and a zero at each location on the second routing grid which does not include the obstacle;
a first Gaussian filter and a first average pooling layer configured to resize the m×m pin image to form an m′×m′ pin image, where m′<<m;
a second Gaussian filter and a second average pooling layer configured to resize the m×m obstacle image to form an m′×m′ obstacle image, where m′<<m;
a series of three convolutional neural network layers configured to receive the m′×m′ pin image and the m′×m′ obstacle image and generate an output series of feature maps;
an output layer configured to receive the output series of feature maps and predict an obstacle avoidance rectilinear Steiner minimal tree (OARSMT) length of wire needed to connect each net of pins;
a computing device configured to estimate the minimum length of wire needed to connect all of the nets of pins;
a placer configured to generate a wiring layout using the minimum length of wire; and
a wiring router configured to connect each of the nets of pins with the minimum length of wire to form the wired circuit based on the wiring layout.

15. The wired circuit of claim 14, wherein:
the first Gaussian filter is configured to apply Gaussian filtering with a standard deviation of σ_{G} and a radius of r_{G};
the first average pooling layer has a kernel size of K_{G}×K_{G} and a stride size of K_{G};
the second Gaussian filter is configured to apply Gaussian filtering with a standard deviation of σ_{G} and a radius of r_{G}; and
the second average pooling layer has a kernel size of K_{G}×K_{G} and a stride size of K_{G}.

16. The wired circuit of claim 15, wherein the series of three convolutional neural network layers further comprises:
a first convolutional neural network layer which has a kernel size of 3×3 and α₁ filters, wherein the α₁ filters are configured to filter the m′×m′ pin image and the m′×m′ obstacle image to isolate images having pin features and obstacle features; and
a first ReLu activation layer configured to detect a first set of pin features and obstacle features in the isolated images and generate a first set of feature maps based on the first set of pin features and obstacle features.

17. The wired circuit of claim 16, wherein the series of three convolutional neural network layers further comprises:
a second convolutional neural network layer which has a kernel size of 3×3 and α₂ filters, wherein the α₂ filters are configured to filter the first set of feature maps to isolate images having pin features and obstacle features; and
a second ReLu activation layer configured to detect a second set of pin features and obstacle features in the isolated images and generate a second set of feature maps based on the first set and the second set of pin features and obstacle features.

18. The wired circuit of claim 17, wherein the series of three convolutional neural network layers further comprises:
a third convolutional neural network layer which has a kernel size of 3×3 and α₃ filters, wherein the α₃ filters are configured to filter the second set of feature maps to isolate images having a third set of pin features and obstacle features; and
a third ReLu activation layer configured to detect a third set of pin features and obstacle features in the isolated images and generate the output series of feature maps based on the first, second and third sets of pin features and obstacles features.

19. The wired circuit of claim 18, wherein m equals 300, m′ equals 10, σ_{G} equals 100, IG equals 100 and K_{G} equals 3, α₁ equals 64, α₂ equals 32 and α₃ equals 8.

20. The wired circuit of claim 16, further comprising:
a flattening block included in the output layer, wherein the flattening block is configured to convert each feature map into a column array;
an output layer rectified linear unit (ReLU) block configured to receive the column array and predict the OARSMT length.
